(19) United States
(12) Patent Application Publication
(10) Pub. No.: US 2023/0261630 A1
(43) Pub. Date: Aug. 17, 2023

(54) ACOUSTIC WAVE DEVICE

(71) Applicant: Murata Manufacturing Co., Ltd., Nagaokakyo-shi (JP)

(72) Inventors: Seiji KAI, Nagaokakyo-shi (JP); Robert B. HAMMOND, Rockville, MD (US); Ventsislav YANTCHEV, Sofia (BG); Patrick TURNER, Portola Valley, CA (US)

(21) Appl. No.: 18/137,650

(22) Filed: Apr. 21, 2023

Related U.S. Application Data
(63) Continuation of application No. PCT/US2021/056293, filed on Oct. 22, 2021.
(60) Provisional application No. 63/104,651, filed on Oct. 23, 2020.

(51) Int. Cl. H03H 9/02; H03H 3/02; H03H 9/17; H03H 9/56

(52) U.S. Cl. CPC H03H 9/02031; H03H 3/02; H03H 9/02228; H03H 9/174; H03H 9/176; H03H 9/562; H03H 9/564; H03H 9/568; H03H 2003/023

(57) ABSTRACT

An acoustic wave device is provided that includes a piezoelectric layer including lithium niobate or lithium tantalate, and a series arm resonator and a parallel arm resonator that each include at least a pair of a first electrode and a second electrode on the piezoelectric layer. The acoustic wave device uses a bulk wave in a first thickness-shear mode. Moreover, a film thickness of a first portion of the piezoelectric layer in the series arm resonator is different from a film thickness of a second portion of the piezoelectric layer in the parallel arm resonator. In each of the series arm resonator and the parallel arm resonator, assuming a film thickness of the piezoelectric layer is d and a distance between centers of the first electrode and the second electrode adjacent to each other is p, a ratio d/p is less than or equal to about 0.5.

### CROSS REFERENCE TO RELATED APPLICATIONS

This application is a continuation of PCT Application No. PCT/US2021/056293, filed Oct. 22, 2021, which claims priority to U.S. Provisional Application No. 63/104,651 filed on Oct. 23, 2020, the entire contents of each of which are hereby incorporated herein by reference.

### TECHNICAL FIELD

The present invention relates to acoustic wave devices each including a piezoelectric layer of lithium niobate or lithium tantalate.

### BACKGROUND

In existing acoustic wave devices, it is difficult both to adjust frequency and to suppress spurious occurrences. Moreover, it is known to change a film thickness of a protective film that covers the electrodes of known acoustic wave devices, for example, the interdigital transducer electrodes, to adjust the frequency of the acoustic wave devices. But, when the protective film covers both series arm and parallel arm resonators of a ladder filter, changes to the film thickness of the protective film similarly affect both the series arm resonators and the parallel arm resonators, which causes the fractional bandwidth to increase, resulting in more spurious occurrences.

### SUMMARY OF THE INVENTION

In view of the foregoing, in exemplary embodiments of the present invention, electronic devices in which a film thickness of a piezoelectric layer is varied between a series arm resonator and a parallel arm resonator, two or more film thicknesses of electrodes (e.g., the interdigital transducer electrodes) can be used, and/or two or more materials of the electrodes can be used. The frequency can be adjusted while spurious occurrences can be suppressed.

According to an exemplary embodiment of the present invention, an acoustic wave device includes a piezoelectric layer including lithium niobate or lithium tantalate and a series arm resonator and a parallel arm resonator each including at least a pair of a first electrode and a second electrode on the piezoelectric layer. The acoustic wave device uses a bulk wave in a first thickness-shear mode, and a film thickness of a first portion of the piezoelectric layer in the series arm resonator is different from a film thickness of a second portion of the piezoelectric layer in the parallel arm resonator.

According to an exemplary embodiment of the present invention, an acoustic wave device includes a piezoelectric layer made of lithium niobate or lithium tantalate and a series arm resonator and a parallel arm resonator each including at least a pair of a first electrode and a second electrode provided on the piezoelectric layer. In each of the series arm resonator and the parallel arm resonator, assuming a film thickness of the piezoelectric layer is d and a distance between centers of the first electrode and the second electrode adjacent to each other is p, a ratio d/p is less than or equal to about 0.5. A film thickness of a first portion of the piezoelectric layer in the series arm resonator is different from a film thickness of a second portion of the piezoelectric layer in the parallel arm resonator.

Moreover, in an exemplary aspect, a mass of the first electrode in the series arm resonator can be different from a mass of the first electrode in the parallel arm resonator, and a mass of the second electrode in the series arm resonator can be different from a mass of the second electrode in the parallel arm resonator. The acoustic wave device can further include a protective film over a thinner of the first portion and the second portion of the piezoelectric layer to cover the first electrode and the second electrode of one of the series arm resonator or the parallel arm resonator.

In addition, the piezoelectric layer can include a step portion, a first connection portion connected to the step portion and a thicker of the first portion and the second portion of the piezoelectric layer, and a second connection portion connected to the step portion and a thinner of the first portion and the second portion of the piezoelectric layer; and at least one of the first connection portion and the second connection portion can include a curved surface.

The piezoelectric layer can include a step portion, a first connection portion connected to the step portion and a thicker of the first portion and the second portion of the piezoelectric layer, and a second connection portion connected to the step portion and a thinner of the first portion and the second portion of the piezoelectric layer; and the step portion can be inclined with respect to a thickness direction of the piezoelectric layer.

According to an exemplary embodiment of the present invention, an acoustic wave device includes a piezoelectric layer made of lithium niobate or lithium tantalate and a series arm resonator and a parallel arm resonator each including at least a pair of a first electrode and a second electrode provided on the piezoelectric layer. In each of the series arm resonator and parallel arm resonator, assuming a film thickness of the piezoelectric layer is d and a distance between centers of the first electrode and the second electrode that are adjacent is p, a ratio d/p is less than or equal to about 0.5. A mass per unit length of an electrode finger of the first electrode in the series arm resonator is different from a mass per unit length of an electrode finger of the first electrode in the parallel arm resonator.

In one exemplary aspect, the ratio d/p can be less than or equal to about 0.24 in each of the series arm resonator and the parallel arm resonator.

Moreover, a film thickness of the first electrode in the series arm resonator can be different from a film thickness of the first electrode in the parallel arm resonator, and a film thickness of the second electrode in the series arm resonator can be different from a film thickness of the second electrode in the parallel arm resonator. A film thickness of the first electrode in the series arm resonator can be thinner than a film thickness of the first electrode in the parallel arm resonator, and a film thickness of the second electrode in the series arm resonator can be thinner than a film thickness of the second electrode in the parallel arm resonator.

In one exemplary aspect, a first material of the first electrode and the second electrode in the series arm resonator can be different from a second material of the first electrode and the second electrode in the parallel arm resonator.

In one exemplary aspect, a mass of the first electrode in the series arm resonator can be less than a mass of the first electrode in the parallel arm resonator, and a mass of the second electrode in the series arm resonator can be less than a mass of the second electrode in the parallel arm resonator.

Moreover, the acoustic wave device can further include a plurality of the series arm resonators or a plurality of the parallel arm resonators, wherein the plurality of series arm resonators or the plurality of parallel arm resonators can include both a resonator that provides a pass band of a ladder filter and a resonator that does not provide the pass band of the ladder filter.

The acoustic wave device can further include a support member including a support substrate that supports the piezoelectric layer. In this aspect, a cavity portion can be provided in the support member and can overlap in a plan view with at least a portion of the first electrode or the second electrode of one of the series arm resonator or the parallel arm resonator.

Assuming a region in which the first electrode and the second electrode that are adjacent and that overlap when viewed in a direction in which the first electrode and the second electrode are opposed is an excitation region, and assuming a metallization ratio of electrodes to the excitation region is MR, MR≤1.75 (d/p)+0.075 can be satisfied in each of the series arm resonator and parallel arm resonator.

Each of the series arm resonator and the parallel arm resonator can include an interdigital transducer electrode, and the first electrode and the second electrode can include electrode fingers of the interdigital transducer electrode.

According to an exemplary embodiment of the present invention, an electronic device includes a support member including a first cavity and a second cavity, a piezoelectric layer that includes lithium niobate or lithium tantalate and that is located on the support member, a first acoustic wave device that uses a first thickness-shear mode and that is within a first region of the piezoelectric layer over the first cavity, and a second acoustic wave device that uses the first thickness-shear mode and that is within a second region of the piezoelectric layer over the second cavity. A first frequency of the first acoustic wave device and a second frequency of the second acoustic wave device are different because: (a) a first thickness of the piezoelectric layer in the first region and a second thickness of the piezoelectric layer in the second region are different and/or (b) a first mass per unit length of electrodes in the first acoustic wave device and a second mass per unit length of electrodes in the second acoustic wave device are different.

The electronic device can further include a third acoustic wave device that uses the first thickness-shear mode and that is within a third region of the piezoelectric layer over a third cavity in the support member. A third frequency of the third acoustic wave device and either the first frequency or the second frequency can be equal.

The first acoustic wave device can be a series arm resonator and the second acoustic wave device can be a parallel arm resonator of a ladder filter.

When a film thickness of the piezoelectric layer is d and a distance between centers of adjacent electrodes in the first and the second acoustic wave devices is p, a ratio d/p can be less than or equal to about 0.5 in each of the first and the second acoustic wave devices. The ratio d/p can be less than or equal to about 0.24 in each of the first and the second acoustic wave devices.

When a metallization ratio of electrodes to the excitation region is MR, MR≤1.75 (d/p)+0.075 can be satisfied in each of the first and the second acoustic wave devices.

The above and other elements, features, steps, characteristics and advantages of the present invention will become more apparent from the following detailed description of the exemplary embodiments with reference to the attached drawings.

### BRIEF DESCRIPTION OF THE DRAWINGS

FIG. 1A is a schematic perspective view showing an acoustic wave device according to a first exemplary embodiment.

FIG. 1B is a plan view showing an electrode structure on a piezoelectric layer.

FIG. 2 is a cross-sectional view taken along the line A-A in FIG. 1A.

FIG. 3A is a schematic elevational cross-sectional view that shows a Lamb wave propagating in a piezoelectric film of an acoustic wave device.

FIG. 3B is a cross-sectional view that shows a bulk wave propagating in a piezoelectric film of an acoustic wave device.

FIG. 4 schematically shows a bulk wave when a voltage is applied across the electrodes of an acoustic wave device.

FIG. 5 is a graph showing the resonant characteristics of the acoustic wave device according to the first exemplary embodiment.

FIG. 6 is a graph showing the relationship between the ratio d/p and the fractional bandwidth of the acoustic wave device as a resonator.

FIG. 7 is a plan view of an acoustic wave device according to a second exemplary embodiment.

FIG. 8 is a reference graph showing an example of the resonant characteristics of the acoustic wave device according to an exemplary embodiment.

FIG. 9 is a graph showing the relationship between a fractional bandwidth and the magnitude of normalized spurious for a large number of acoustic wave resonators.

FIG. 10 is a graph showing the relationship among the ratio d/2p, the metallization ratio MR, and the fractional bandwidth.

FIG. 11 is a diagram showing a map of a fractional bandwidth of the Euler angles (0°, θ, ψ) of LiNbO₃ when the ratio d/p is brought close to zero without limit.

FIGS. 12 and 13 are cross-sectional views of electronic devices including acoustic wave devices according to a third exemplary embodiment.

FIG. 14 shows an example arrangement of a ladder filter with series arm and parallel arm resonators.

FIGS. 15 and 16 are cross-sectional views of possible modifications to the electronic devices shown in FIGS. 12 and 13.

FIGS. 17 and 18 are cross-sectional views of electronic devices including acoustic wave devices according to a fourth exemplary embodiment.

FIGS. 19-22 are cross-sectional views of electronic devices including acoustic wave devices according to a fifth exemplary embodiment.

FIGS. 23-29 are cross-sectional views showing a method of manufacturing an electronic device according to a sixth exemplary embodiment.

FIG. 30 is a cross-sectional view of an electronic device including acoustic wave devices according to a seventh exemplary embodiment.

FIGS. 31-38 are cross-sectional views showing a method of manufacturing an electronic device according to an eighth exemplary embodiment.

### DETAILED DESCRIPTION OF THE EMBODIMENTS

Exemplary embodiments of the present invention include a piezoelectric layer 2 made of lithium niobate or lithium tantalate, and first and second electrodes 3, 4 opposed in a direction that intersects with a thickness direction of the piezoelectric layer 2.

In operation, a bulk wave in a first thickness-shear mode is used. In addition, the first and the second electrodes 3, 4 can be adjacent electrodes, and, when a thickness of the piezoelectric layer 2 is d and a distance between a center of the first electrode 3 and a center of the second electrode 4 is p (also referred to as a “pitch”), a ratio d/p can be less than or equal to about 0.5, for example. With this configuration, the size of the acoustic wave device can be reduced, and the Q value can be increased.

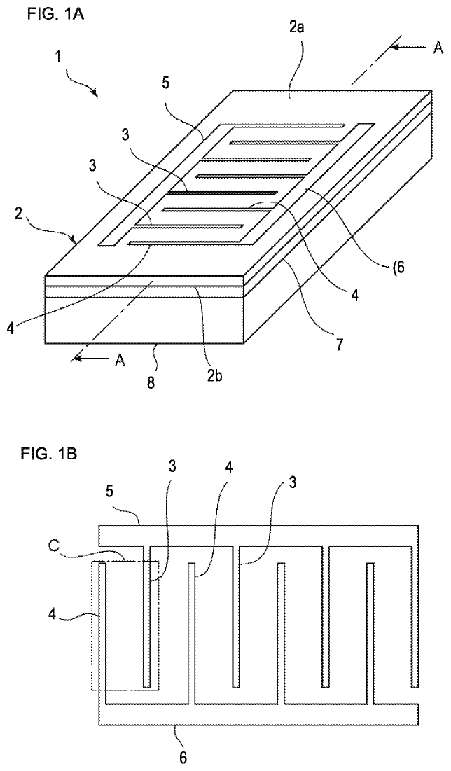

In an exemplary aspect, an acoustic wave device 1 includes a piezoelectric layer 2 made of LiNbO₃. The piezoelectric layer 2 can also be made of LiTaO₃. The cut angle of LiNbO₃ or LiTaO₃ can be Z-cut and can be rotated Y-cut or X-cut. A propagation direction of Y propagation or X propagation of about ±30° can be used, for example. The thickness of the piezoelectric layer 2 is not limited and can be greater than or equal to about 50 nm and can be less than or equal to about 1000 nm, for example, to effectively excite a first thickness-shear mode in operation. The piezoelectric layer 2 has opposed first and second major surfaces 2a, 2b. The electrodes 3, 4 are provided on the first major surface 2a. The electrodes 3 are examples of the “first electrode,” and the electrodes 4 are examples of the “second electrode.” In FIG. 1A and FIGS. 1B, the plurality of electrodes 3 is connected to a first busbar 5, and the plurality of electrodes 4 is connected to a second busbar 6. The electrodes 3, 4 can be interdigitated with each other. The electrodes 3, 4 each can have a rectangular shape and can have a length direction. In a direction perpendicular to the length direction, each of the electrodes 3 and an adjacent one of the electrodes 4 are opposed to each other. The length direction of the electrodes 3, 4 and the direction perpendicular to the length direction of the electrodes 3, 4 both are directions that intersect with a thickness direction of the piezoelectric layer 2. For this reason, each of the electrodes 3 and the adjacent one of the electrodes 4 can be regarded as being opposed to each other in the direction that intersects with the thickness direction of the piezoelectric layer 2. Alternatively, the length direction of the electrodes 3, 4 can be interchanged by the direction perpendicular to the length direction of the electrodes 3, 4, shown in FIGS. 1A and 1B. In other words, in FIGS. 1A and 1B, the electrodes 3, 4 can be extended in a direction in which the first busbar 5 and the second busbar 6 extend. In this case, the first busbar 5 and the second busbar 6 extend in the direction in which the electrodes 3, 4 extend in FIGS. 1A and 1B. Pairs of adjacent electrodes 3 connected to one potential and electrodes 4 connected to the other potential are provided in the direction perpendicular to the length direction of the electrodes 3, 4. A state where the electrodes 3, 4 are adjacent to each other does not mean that the electrodes 3, 4 are in direct contact with each other and instead means that the electrodes 3, 4 are disposed via a gap between each other. When the electrodes 3, 4 are adjacent to each other, no electrode connected to a hot electrode or a ground electrode, including the other electrodes 3, 4 are disposed between the electrodes 3, 4.

The number of the pairs of electrodes 3, 4 is not necessarily an integer number of pairs and can be 1.5 pairs, 2.5 pairs, or the like. For example, 1.5 pairs of electrodes means that there are three electrodes 3, 4, two of which is in a pair of electrodes and one of which is not in a pair. A distance between the centers of the electrodes 3, 4, that is, the “pitch” of the electrodes 3, 4, can fall within the range of greater than or equal to about 1 μm and less than or equal to about 10 μm, for example. A distance between the centers of the electrodes 3, 4 can be a distance between the center of the width dimension of the electrodes 3, 4 in the direction perpendicular to the length direction of the electrodes 3, 4. In addition, when there is more than one electrode 3, 4 (e.g., when the number of electrodes 3, 4 is two such that the electrodes 3, 4 define an electrode pair, or when the number of electrodes 3, 4 is three or more such that electrodes 3, 4 define 1.5 or more electrode pairs), a distance between the centers of the electrodes 3, 4 (i.e., the “pitch”) means an average of a distance between any adjacent electrodes 3, 4 of the 1.5 or more electrode pairs. The width of each of the electrodes 3, 4, that is, the dimension of each of the electrodes 3, 4 in the opposed direction that is perpendicular to the length direction, can fall within the range of greater than or equal to about 150 nm and less than or equal to about 1000 nm, for example. A distance between the centers of the electrodes 3, 4 can be a distance between the center of the dimension of the electrode 3 in the direction perpendicular to the length direction of the electrode 3 (width dimension) and the center of the dimension of the electrode 4 in the direction perpendicular to the length direction of the electrode 4 (width dimension).

Because the Z-cut piezoelectric layer can be used, the direction perpendicular to the length direction of the electrodes 3, 4 is a direction perpendicular to a polarization direction of the piezoelectric layer 2. When a piezoelectric body with another cut angle is used as the piezoelectric layer 2, this does not apply. For purposes of this disclosure, the term “perpendicular” is not limited only to a strictly perpendicular case and can be substantially perpendicular (an angle formed between the direction perpendicular to the length direction of the electrodes 3, 4 and the polarization direction can be, for example, about 90°±10°).

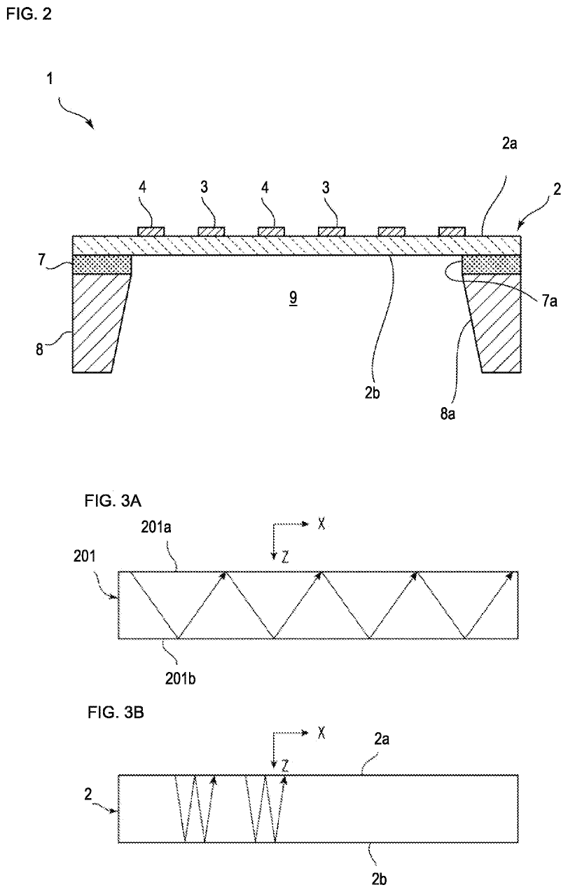

As further shown, a support substrate 8 can be laminated via an electrically insulating layer or dielectric film 7 to the second major surface 2b of the piezoelectric layer 2. As shown in FIG. 2, the electrically insulating layer 7 can have a frame shape and can include an opening portion 7a, and the support substrate 8 can have a frame shape and can include an opening portion 8a. With this configuration, a cavity portion 9 can be formed. The cavity portion 9 can be provided so as not to impede vibrations of an excitation region C of the piezoelectric layer 2. Therefore, the support substrate 8 can be laminated to the second major surface 2b via the electrically insulating layer 7 at a location that does not overlap a portion where at least one electrode pair is provided. The electrically insulating layer 7 does not need to be provided. Therefore, the support substrate 8 can be laminated directly or indirectly on the second major surface 2b of the piezoelectric layer 2. As shown in FIG. 3, the electrodes 3, 4 are disposed on a top surface of the piezoelectric layer 2, which is facing away from the cavity portion 9. In alternative aspects, the electrodes 3, 4 can be disposed on a bottom surface of the piezoelectric layer 2, which is facing the cavity portion 9, or can be on both surfaces of the piezoelectric layer 2.

In an exemplary aspect, the electrically insulating layer 7 can be made of silicon oxide. Other than silicon oxide, an appropriate electrically insulating material, such as silicon oxynitride and alumina, can also be used. The support substrate 8 can be made of Si or other suitable material. A plane direction of the Si can be (100) or (110) or (111). High-resistance Si with a resistivity higher than or equal to about 4 kΩ, for example, can be used. The support substrate 8 can also be made of an appropriate electrically insulating material or an appropriate semiconductor material. Examples of the material of the support substrate 8 include a piezoelectric body, such as aluminum oxide, lithium tantalate, lithium niobate, and quartz crystal; various ceramics, such as alumina, magnesia, sapphire, silicon nitride, aluminum nitride, silicon carbide, zirconia, cordierite, mullite, steatite, and forsterite; a dielectric, such as diamond and glass; and a semiconductor, such as gallium nitride.

The first and the second electrodes 3, 4 and the first and the second busbars 5, 6 can be made of an appropriate metal or alloy, such as Al and AlCu alloy. The first and the second electrodes 3, 4 and the first and second busbars 5, 6 can include a structure such as an Al film that can be laminated on a Ti film. An adhesion layer other than a Ti film can be used.

To drive the acoustic wave device 1, alternating-current voltage is applied between the first and the second electrodes 3, 4. More specifically, alternating-current voltage is applied between the first and the second busbar 5, 6 to excite a bulk wave in a first thickness-shear mode in the piezoelectric layer 2. In the acoustic wave device 1, when the thickness of the piezoelectric layer 2 is d and a distance between the centers of adjacent first and second electrodes 3, 4 of the electrode pairs is p, the ratio d/p can be less than or equal to about 0.5, for example. For this reason, a bulk wave in the first thickness-shear mode can be effectively excited, which results in good resonant characteristics being obtained. The ratio d/p can less than or equal to about 0.24, and, in this case, further good resonant characteristics can be obtained. When there is more than one electrode, the distance p between the centers of the adjacent electrodes 3, 4 is an average distance of the distance between the centers of any adjacent electrodes 3, 4.

With the above configuration, the Q value of the acoustic wave device 1 is unlikely to decrease, even when the number of electrode pairs is reduced for size reduction. The Q value is unlikely to decrease if the number of electrode pairs is reduced because the acoustic wave device 1 is a resonator that needs no reflectors on both sides, and therefore, a propagation loss is small. It should be appreciated that no reflectors are needed because a bulk wave in a first thickness-shear mode is used.

The difference between a Lamb wave used in known acoustic wave devices and a bulk wave in the first thickness-shear mode is described with reference to FIGS. 3A and 3B.

FIG. 3A is a schematic elevational cross-sectional view for illustrating a Lamb wave propagating in a piezoelectric film of an acoustic wave device as described in Japanese Unexamined Patent Application Publication No. 2012-257019, for example.

The wave propagates in a piezoelectric film 201 as indicated by the arrows in FIG. 3A. In the piezoelectric film 201, a first major surface 201a and a second major surface 201b are opposed to each other, and a thickness direction connecting the first major surface 201a and the second major surface 201b is a Z direction. An X direction is a direction in which electrode fingers of an interdigital transducer electrode are arranged. As shown in FIG. 3A, a Lamb wave propagates in the X direction. The Lamb wave is a plate wave, so the piezoelectric film 201 vibrates as a whole. However, the wave propagates in the X direction. Therefore, resonant characteristics are obtained by arranging reflectors on both sides. For this reason, a wave propagation loss occurs, and the Q value decreases when the size is reduced, that is, when the number of electrode pairs is reduced.

In contrast, as shown in FIG. 3B, in the acoustic wave device 1, a vibration displacement is caused in the thickness-shear direction, so the wave propagates substantially in the direction connecting the first and the second major surfaces 2a, 2b of the piezoelectric layer 2, that is, the Z direction, and resonates. In other words, the X-direction component of the wave is significantly smaller than the Z-direction component. Since the resonant characteristics are obtained from the propagation of the wave in the Z direction, no reflectors are needed. Thus, there is no propagation loss caused when the wave propagates to reflectors. Therefore, even when the number of electrode pairs is reduced to reduce size, the Q value is unlikely to decrease.

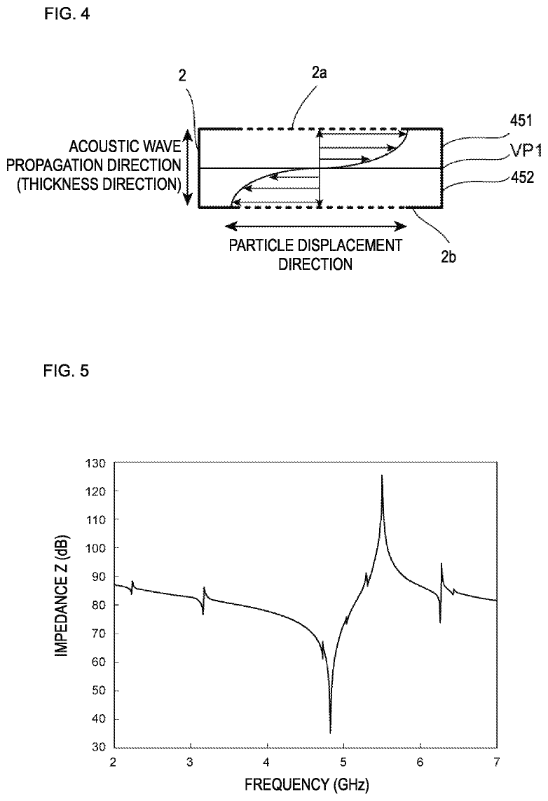

As shown in FIG. 4, the amplitude direction of the bulk wave in the first thickness-shear mode is opposite between a first region 451 included in the excitation region C of the piezoelectric layer 2 and a second region 452 included in the excitation region C, where the excitation region C is shown in FIG. 1B. FIG. 4 schematically shows a bulk wave when a higher voltage is applied to the electrodes 4 than a voltage applied the electrodes 3. The first region 451 is a region in the excitation region C between the first major surface 2a and a virtual plane VP1 that is perpendicular to the thickness direction of the piezoelectric layer 2 and that divides the piezoelectric layer 2 into two. The second region 452 is a region in the excitation region C between the virtual plane VP1 and the second major surface 2b.

As described above, the acoustic wave device 1 includes at least one electrode pair. However, the wave is not propagated in the X direction, so the number of electrode pairs 4 does not necessarily need to be two or more. In other words, only one electrode pair can be provided.

For example, the first electrode 3 is an electrode connected to a hot potential, and the second electrode 4 is an electrode connected to a ground potential. Of course, the first electrode 3 can be connected to a ground potential, and the second electrode 4 can be connected to a hot potential. Each first or second electrode 3, 4 is connected to a hot potential or is connected to a ground potential as described above, and no floating electrode is provided.

FIG. 5 is a graph showing the resonant characteristics of the acoustic wave device 1. The design parameters of the acoustic wave device 1 having the resonant characteristics are as follows. The piezoelectric layer 2 is made of LiNbO₃ with Euler angles of (0°, 0°, 90°) and has a thickness of about 400 nm, for example. But, as explained above, the piezoelectric layer 2 can be LiTaO₃, and other suitable Euler angles and thicknesses can be used according to alternative exemplary aspects.

When viewed in a direction perpendicular to the length direction of the first and the second electrodes 3, 4, the length of a region in which the first and the second electrodes 3, 4 overlap, that is, the excitation region C, can about 40 μm, the number of electrode pairs of electrodes 3, 4 can be 21, the distance between the centers of the first and the second electrodes 3, 4 can be about 3 μm, the width of each of the first and the second electrodes 3, 4 can be about 500 nm, and the ratio d/p can be about 0.133, for example.

The electrically insulating layer 7 can be made of a silicon oxide film having a thickness of about 1 μm, for example.

The support substrate 8 can be made of Si, for example.

The length of the excitation region C can be along the length direction of the first and the second electrodes 3, 4.

The distance between any adjacent electrodes of the electrode pairs can be equal or substantially equal within manufacturing and measurement tolerances among all of the electrode pairs. In other words, the first and the second electrodes 3, 4 can be disposed at a constant pitch.

As illustrated in FIG. 5, although no reflectors are provided, good resonant characteristics with a fractional bandwidth of about 12.5% can be obtained.

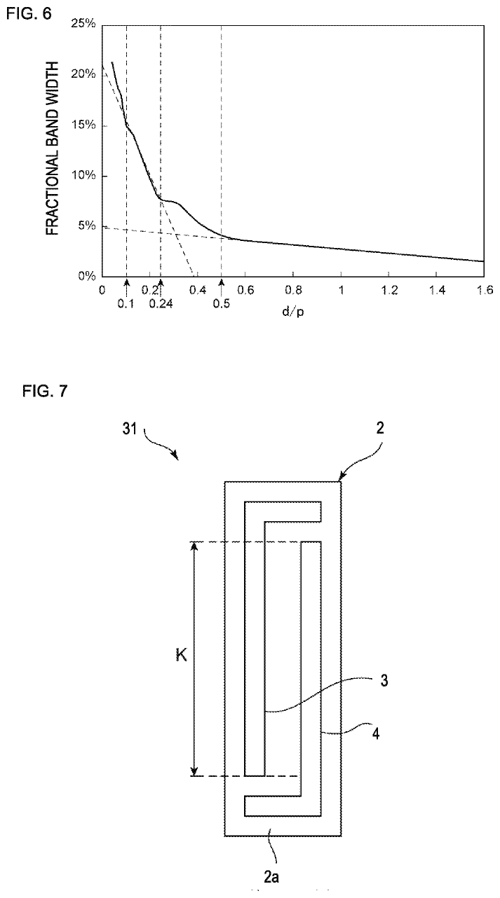

When the thickness of the piezoelectric layer 2 is d and the distance between the centers of the electrode pairs is p, the ratio d/p can be less than or equal to about 0.5 or can be less than or equal to about 0.24, for example. The ratio d/p will be further discussed with reference to FIG. 6 below.

Acoustic wave devices can be provided with different ratios d/p as in the case of the acoustic wave device having the resonant characteristics shown in FIG. 5. FIG. 6 is a graph showing the relationship between the ratio d/p and the fractional bandwidth when the acoustic wave device 1 is used as a resonator.

As is apparent from the non-limiting example shown in FIG. 6, when the ratio d/p>0.5, the fractional bandwidth is lower than about 5%, even when the ratio d/p is adjusted. In contrast, in the case where the ratio d/p≤0.5, the ratio d/p changes within the range, and the fractional bandwidth can be set to about 5% or higher, that is, a resonator having a high coupling coefficient can be provided, for example. In the case where the ratio d/p is lower than or equal to about 0.24, the fractional bandwidth can be increased to about 7% or higher, for example. In addition, when the ratio d/p is adjusted within the range, a resonator having a further wide fractional bandwidth can be obtained, so a resonator having a further high coupling coefficient can be achieved. Therefore, it has been discovered and confirmed that, when the ratio d/p is set to about 0.5 or less, for example, a resonator that uses a bulk wave in the first thickness-shear mode with a high coupling coefficient can be provided.

As described above, at least one electrode pair can be one pair, and, in the case of one electrode pair, p is defined as the distance between the centers of the adjacent first and second electrodes 3, 4. In the case of 1.5 or more electrode pairs, an average distance of the distance between the centers of any adjacent electrodes 3, 4 can be defined as p.

For the thickness d of the piezoelectric layer 2, when the piezoelectric layer 2 has thickness variations, an averaged value of the thicknesses can be used.

FIG. 7 is a plan view of an acoustic wave device 31 according to a second exemplary embodiment. In the acoustic wave device 31, one electrode pair including the first and the second electrodes 3, 4 is provided on the first major surface 2a of the piezoelectric layer 2. In FIG. 7, K is an overlap width. As described above, in the acoustic wave device 31, the number of electrode pairs of can be one. In this case as well, when the ratio d/p is less than or equal to about 0.5, for example, a bulk wave in a first thickness-shear mode can be effectively excited.

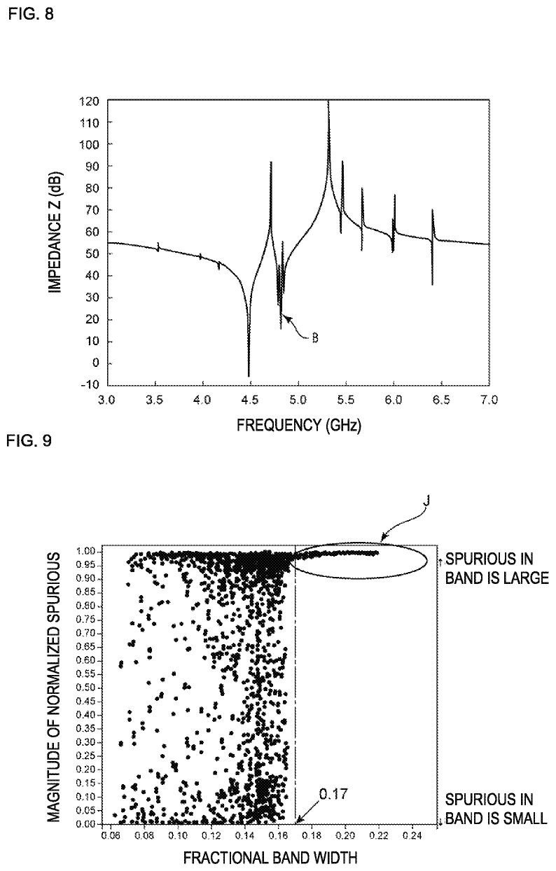

In the acoustic wave device 31, a metallization ratio MR of any adjacent first and second electrodes 3, 4 to the excitation region C, i.e., a region in which any adjacent electrodes 3, 4 overlap when viewed in the opposed direction, can satisfy MR≤1.75 (d/p)+0.075, effectively reducing spurious occurrences. This reduction will be described with reference to FIGS. 8 and 9. FIG. 8 is a reference graph showing an example of the resonant characteristics of the acoustic wave device 31. The spurious occurrence indicated by the arrow B appears between a resonant frequency and an anti-resonant frequency. The ratio d/p can be set to about 0.08, and the Euler angles of LiNbO₃ can be set to (0°, 0°, 90°), for example. The metallization ratio MR can be set to about 0.35, for example.

The metallization ratio MR will be described with reference to FIG. 1B. In the electrode structure of FIG. 1B, when focusing on one electrode pair, it is assumed that only the one electrode pair is provided. In this case, the portion surrounded by the alternate long and short dashed line C is the excitation region. The excitation region C includes, when the first and the second electrodes 3, 4 are viewed in the direction perpendicular to the length direction of the first and the second electrodes 3, 4, that is, the opposed direction, a first region of the first electrode 3 overlapping with the second electrode 4, a second region of the second electrode 4 overlapping with the first electrode 3, and a third region in which the first and the second electrodes 3, 4 overlap in a region between the first and the second electrodes 3, 4. Then, the ratio of the area of the first and the second electrodes 3, 4 in the excitation region C to the area of the excitation region C is the metallization ratio MR. In other words, the metallization ratio MR is the ratio of the area of a metallization portion to the area of the excitation region C.

When a plurality of electrode pairs is provided, the ratio of a metallization portion included in the total excitation region to the total area of the excitation region is the metallization ratio MR.

FIG. 9 is a graph showing the relationship between a fractional bandwidth and a magnitude of normalized spurious for a large number of acoustic wave resonators in which a phase rotation amount of impedance of spurious is normalized by 180° as the magnitude of spurious. The phase rotation amount of impedance is an indicator of the magnitude of spurious, which is related to the impedance ratio. The impedance ratio relates to the difference between the minimum value and the maximum value of the impedance, while the phase rotation amount of impedance relates to the peak value of the impedance. For the fractional bandwidth, the film thickness of the piezoelectric layer 2 and the dimensions of the first and the second electrodes 3, 4 are variously changed and adjusted. FIG. 8 is graph showing the resonant characteristics when material of the piezoelectric layer 2 is Z-cut LiNbO₃, and similar resonant characteristics can be obtained when the material of the piezoelectric layer 2 uses another cut angle.

In a region surrounded by the ellipse J in FIG. 9, the spurious is about 1.0 and large. As is apparent from FIG. 9, when the fractional bandwidth exceeds about 0.17, that is, about 17%, large spurious having a spurious level greater than or equal to one appears in a pass band, even when parameters of the fractional bandwidth are changed. In other words, as in the case of the resonant characteristics shown in FIG. 8, large spurious indicated by the arrow B appears in the pass band. Thus, the fractional bandwidth is preferably lower than or equal to about 17%, for example. In this case, spurious can be reduced by adjusting the film thickness of the piezoelectric layer 2, the dimensions of the first and the second electrodes 3, 4, and the like.

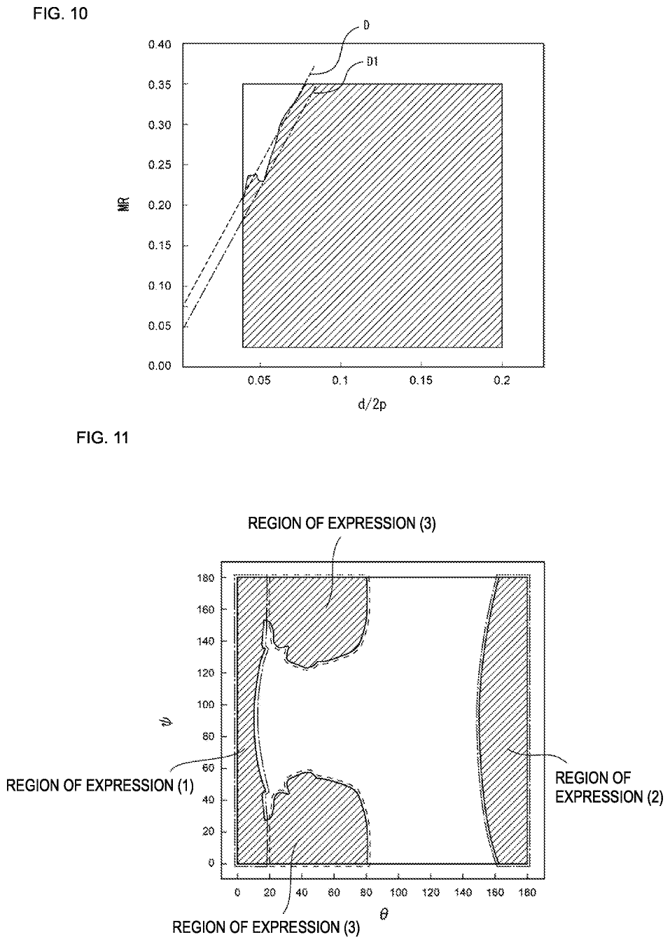

FIG. 10 is a graph showing the relationship among the ratio d/2p, the metallization ratio MR, and the fractional bandwidth. The fractional bandwidths of various acoustic wave devices with different ratios d/2p and with different metallization ratios MR are measured. The hatched portion on the right-hand side of the dashed line D in FIG. 10 is a region in which the fractional bandwidth is lower than or equal to about 17%, for example. The dashed line D between the hatched region and a non-hatched region is expressed by MR=3.5 (d/2p)+0.075=1.75 (d/p)+0.075. When the metallization ratio MR satisfies MR≤1.75 (d/p)+0.075, the fractional bandwidth can be set to about 17% or lower, for example. Additionally, FIG. 10 shows a long- and short-dashed line D1 expressed by MR=3.5 (d/2p)+0.05. When the metallization ratio MR satisfies MR≤1.75 (d/p)+0.05, the fractional bandwidth can be reliably set to about 17% or lower, for example.

FIG. 11 is a diagram showing a map of the fractional bandwidth for the Euler angles (0°, e, w) of LiNbO₃ when the ratio d/p is brought close to zero without limit. The hatched portions in FIG. 11 are regions in which the fractional bandwidth is at least about 5% or higher, and the boundaries of the hatched portions are approximated by the following expressions (1), (2), and (3):

(0°±10°, 0° to 20°, any ψ)

(0°±10°, 20° to 80°, 0° to 60° (1−(θ−50)²/900)^{1/2}) or (1)

(0°±10°, 20° to 80°, [180°−60° (1−(θ−50)²/900)^{1/2}] to 180°) (2)

(0°±10°, [180°−30° (1−(ψ−90)²/8100)^{1/2}] to 180°, any ψ) (3)

Therefore, when the Euler anglers of the material used for the piezoelectric layer 2 of an acoustic wave resonator satisfy the above expressions (1), (2), and (3), the fractional bandwidth of the acoustic wave resonator can be sufficiently widened.

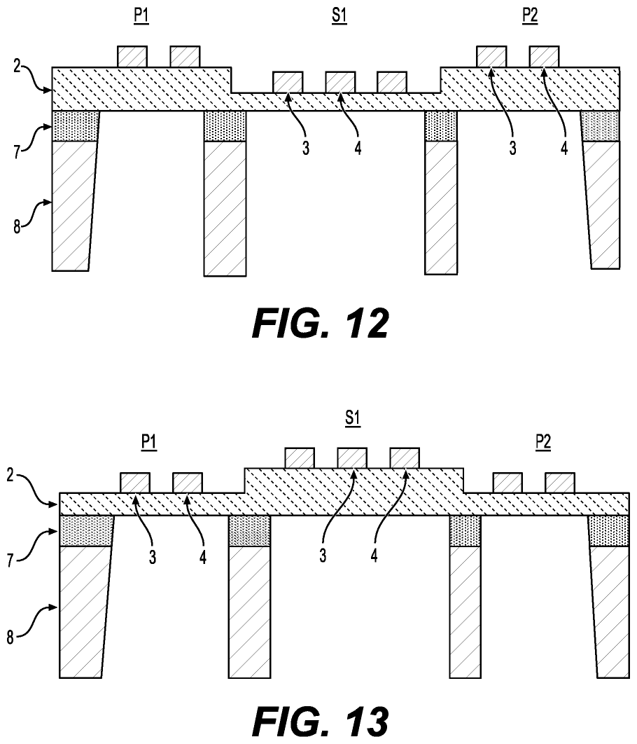

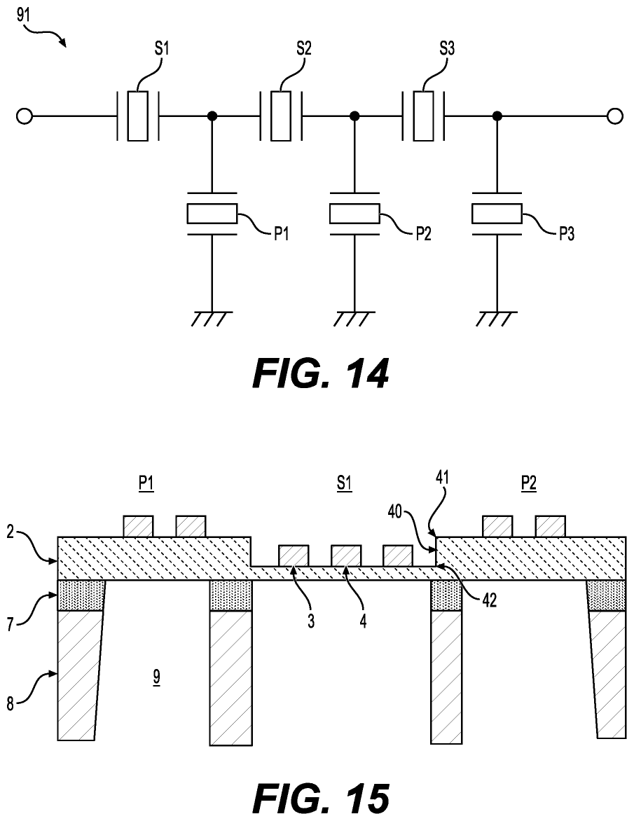

FIGS. 12 and 13 show electronic devices according to a third exemplary embodiment. The electronic devices shown in FIGS. 12 and 13 can include a plurality of acoustic wave devices, including those acoustic wave devices 1, 31 disclosed with respect to the first and the second embodiments discussed above. The acoustic wave devices of the electronic devices can be arranged, for example, as a ladder filter 91 as shown in FIG. 14. In alternative aspects, the acoustic wave devices in the electronic devices shown in FIGS. 12 and 13 do not have to be arranged as a ladder filter and can have other suitable arrangements. For example, the electronic devices shown in FIGS. 12 and 13 can include first and second acoustic wave devices or can include first, second, and third acoustic wave devices.

A ladder filter 91 as shown in FIG. 14 can include acoustic wave devices, including, for example, the acoustic wave device 1, 31 discussed above with respect to the first and the second embodiments, as series arm resonators S1, S2, S3 and as parallel arm resonators P1, P2, P3, which can also be considered “shunt” resonators in an exemplary aspect. FIG. 14 shows an example of a ladder-filter arrangement with series arm resonators S1, S2, S3 and parallel arm resonators P1, P2, P3.

The electronic devices shown in FIGS. 12 and 13 include a support substrate 8, a piezoelectric layer 2 laminated on the support substrate 8, and first and second electrodes 3, 4, which can be the electrode fingers of an interdigital transducer electrode, on the piezoelectric layer 2. The electronic devices in FIGS. 12 and 13 can use a first thickness-shear mode. An electrically insulating layer or dielectric film 7, which can be made of, for example, SiO₂ or the like, can be provided between the support substrate 8 and the piezoelectric layer 2. The piezoelectric layer 2 can be provided on a support member that includes the support substrate 8 and the electrically insulating layer 7.

In FIGS. 12 and 13, the film thickness of the piezoelectric layer 2 in each series arm resonator S1, S2, S3 (only series arm resonator S1 is shown in FIGS. 12 and 13) is different from the film thickness of the piezoelectric layer 2 in each parallel arm resonator P1, P2, P3 (only parallel arm resonator P1, P2 are shown in FIGS. 12 and 13). For example, as shown in FIG. 12, the film thickness of the piezoelectric layer 2 of each series arm resonator S1, S2, S3 can be thinner than the film thickness of the piezoelectric layer 2 of each parallel arm resonator P1, P2, P3. Thus, the resonant frequency of each series arm resonator S1, S2, S3 can be increased compared to the resonant frequency of each parallel arm resonator P1, P2, P3. Alternatively, as shown in FIG. 13, the film thickness of the piezoelectric layer 2 of each series arm resonator S1, S2, S3 can be thicker than the film thickness of the piezoelectric layer 2 of each parallel arm resonator P1, P2, P3. Thus, the resonant frequency of each series arm resonator S1, S2, S3 can be decreased compared to the resonant frequency of each parallel arm resonator P1, P2, P3.

It should be appreciated that other arrangements are also possible. For example, the film thicknesses of the piezoelectric layer 2 in each series arm resonator S1, S2, S3 can be different from each other, and/or the film thicknesses of the piezoelectric layer 2 in each parallel arm resonator P1, P2, P3 can be different from each other.

If the electronic device includes first and second acoustic wave devices, then the film thicknesses of the piezoelectric layer 2 in each of the first and the second acoustic wave devices can be different from each other (t1≠t2, where t1 is the thickness of piezoelectric layer 2 in the first acoustic wave device and t2 is the thickness of piezoelectric layer 2 in the second acoustic wave device).

If the electronic device further includes a third acoustic wave device, then the film thickness of the piezoelectric layer 2 of the third acoustic wave device can be either (a) the same as the film thickness of the piezoelectric layer 2 of either the first acoustic wave device or the second acoustic wave device (t3=t1 or t3=t2, where t3 is the thickness of piezoelectric layer 2 in the third acoustic wave device) or (b) different from the film thicknesses of the piezoelectric layer of both the first and the second acoustic wave devices (t1≠t2≠t3).

In FIG. 14, the series arm resonators S1, S3, S3 and the parallel arm resonators P1, P2, P3 are resonators that can be used to configure the pass band of the ladder filter 91.

One of the series arm resonators S1, S2, S3 can define and function as a series trap that does not configure the pass band of the ladder filter 91. The series arm resonators S1, S2, S3 can include both a resonator that configures the pass band of the ladder filter and a resonator that does not configure the pass band of the ladder filter. In addition, one of the parallel arm resonators P1, P2, P3 can define and function as a parallel trap that does not configure the pass band of the ladder filter. The parallel arm resonators P1, P2, P3 can include both a resonator that configures the pass band of the ladder filler and a resonator that does not configure the pass band of the ladder filter. In these configurations, significant adjustment of the frequency can be achieved.

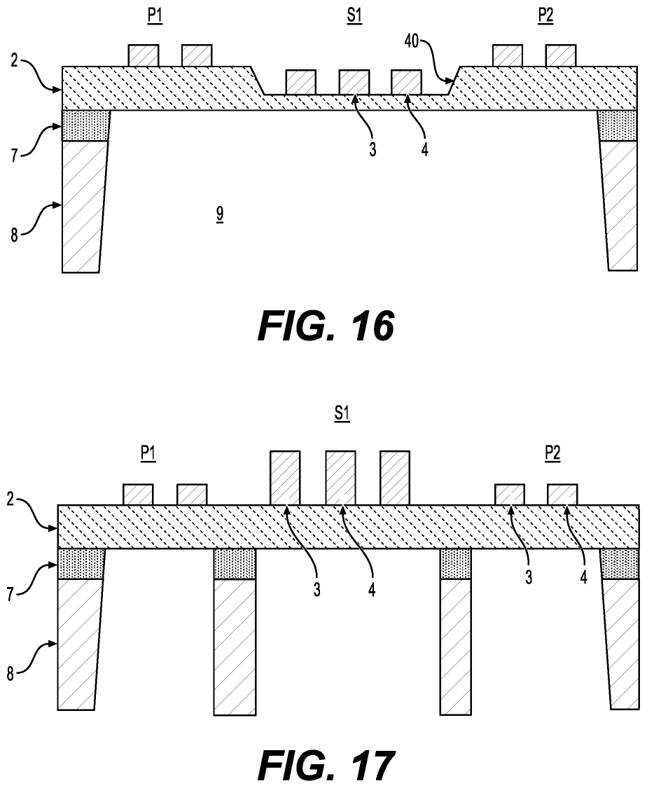

FIGS. 15 and 16 shows possible modifications to the electronic devices shown in FIGS. 12 and 13. As shown in FIGS. 15 and 16, the piezoelectric layer 2 can include thicker portions and thinner portions. Where the film thickness of the piezoelectric layer 2 varies, the piezoelectric layer 2 can include a step portion 40, a first connection portion 41 connected to the step portion 40 and the thicker portion of the piezoelectric layer 2, and a second connection portion 42 connected to the step portion 40 and the thinner portion of the piezoelectric layer 2.

In an alternative aspect, at least one of the first connection portion and the second connection portion can include a curved surface shape as shown in FIG. 16. Alternatively, the step portion can be inclined with respect to a thickness direction of the piezoelectric layer. In these cases, a break of a wiring portion formed in the portion where the film thickness varies can be suppressed.

As shown in FIGS. 15 and 16, a cavity portion 9 can be provided to at least partially overlap with the first electrode 3 and/or the second electrode 4 of each series arm resonator S1, S2, S3 or each parallel arm resonator P1, P2, P3 in a plan view. The first and the second electrodes 3, 4 of each series arm resonator S1, S2, S3 and the first and the second electrodes 3, 4 of each parallel arm resonator P1, P2, P3 can be formed to overlap the same cavity portion 9 in a plan view. Again, it is noted that the first electrode 3 and/or the second electrode 4 can be disposed on the lower surface of the piezoelectric plate 2 in an alternative aspect to face the cavity portion 9.

The cavity portion 9 can be a through-hole extending through the support substrate 8 and the electrically insulating layer 7, i.e., through the support member. The cavity portion 9 can be a cavity with a bottom portion. The cavity can be provided only in the electrically insulating layer 7. When the support member includes only the support substrate 7, the cavity or the through-hole is provided only in the support substrate 7.

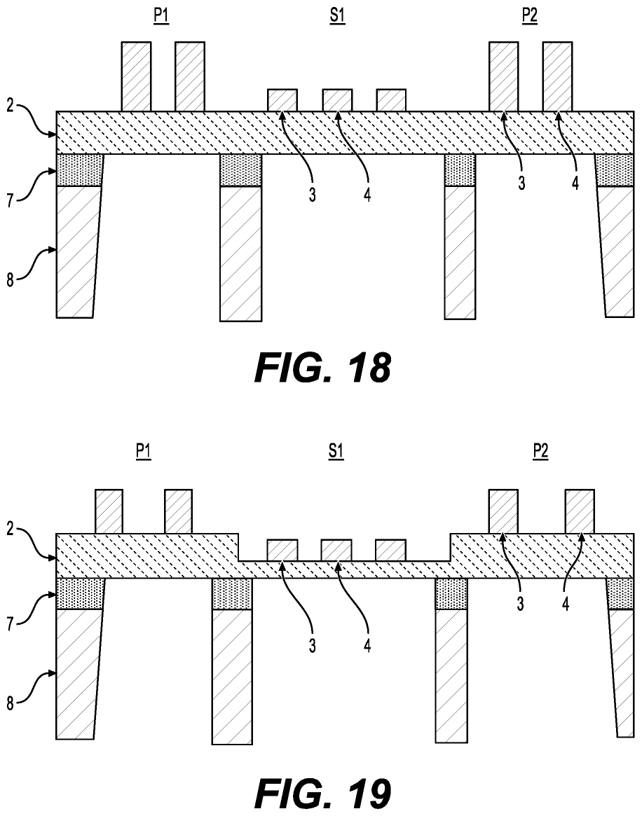

FIGS. 17 and 18 show electronic devices according to a fourth exemplary embodiment of the present invention. As with the electronic devices shown in FIGS. 12 and 13, the electronic devices shown in FIGS. 17 and 18 can include a plurality of acoustic wave devices, including those acoustic wave devices 1, 31 disclosed with respect to the first and the second embodiments discussed above, that can be arranged, for example, as a ladder filter 91 as shown, for example, in FIG. 14. The plurality of acoustic wave devices in the electronic devices shown in FIGS. 17 and 18 do not have to be arranged as a ladder filter and can have other suitable arrangements. Only series arm resonator S1 and parallel arm resonators P1, P2 are shown in FIGS. 17 and 18, but the ladder filter can also use series arm resonators S2, S3 and parallel arm resonator P3.

The electronic devices shown in FIGS. 17 and 18 include a support substrate 8, a piezoelectric layer 2 laminated on the support substrate 8, and first and second electrodes 3, 4, which can be the electrode fingers of an interdigital transducer electrode, on the piezoelectric layer 2. The electronic devices in FIGS. 17 and 18 can use a first thickness-shear mode. An electrically insulating layer or dielectric film 7, which can be made of, for example, SiO₂ or the like, can be provided between the support substrate 8 and the piezoelectric layer 2. The piezoelectric layer 2 can be provided on a support member that includes the support substrate 8 and the electrically insulating layer 7. Although shown on an upper surface of the piezoelectric plate 2, it is noted that the first electrode 3 and/or the second electrode 4 can be disposed on the lower surface of the piezoelectric plate 2 in an alternative aspect to face the cavity portion 9.

The mass (that is, the product of the volume and the density of each of the first and the second electrodes 3, 4) or mass per unit length (that is, the product of the thickness, the width, and the density of each of the first and the second electrodes 3, 4) of each of the first and the second electrodes 3, 4 in the series arm resonators S1, S2, S3 can be different from the mass or mass per unit length of each of the first and the second electrodes 3, 4 in the parallel arm resonators P1, P2, P3. For example, as shown in FIG. 18, the film thicknesses of the first and the second electrodes 3, 4 of the series arm resonators S1, S2, S3 can be thinner than the film thicknesses of the first and the second electrodes 3, 4 of the parallel arm resonators P1, P2, P3. Alternatively, the density of the material of the first and the second electrodes 3, 4 of the series arm resonators S1, S2, S3 can be lower than the density of the material of the first and the second electrodes 3, 4 of the parallel arm resonators P1, P2, P3. Thus, the resonant frequency of the series arm resonators S1, S2, S3 can be increased as compared to the resonant frequency of the parallel arm resonators P1, P2, P3. As shown in FIG. 17, the film thicknesses of the first and the second electrodes 3, 4 of the series arm resonators S1, S2, S3 can be thicker than the film thicknesses of the first and the second electrodes 3, 4 of the parallel arm resonators P1, P2, P3. Alternatively, the density of the material of the first and the second electrodes 3, 4 of the series arm resonators S1, S2, S3 can be higher than the density of the material of the first and the second electrodes 3, 4 of the parallel arm resonators P1, P2, P3. Thus, the resonant frequency of the series arm resonators S1, S2, S3 can be decreased as compared to the resonant frequency of the parallel arm resonators P1, P2, P3.

It should be appreciated that other arrangements are also possible. For example, the masses or mass per unit length of the first and the second electrodes 3, 4 in each series arm resonator S1, S2, S3 can be different, because of different thicknesses and/or densities, from each other, and/or the masses or mass per unit length of the first and the second electrodes 3, 4 in each parallel arm resonator P1, P2, P3 can be different, because of different thicknesses and/or densities, from each other.

If the electronic device includes first and second acoustic wave devices, then the masses or mass per unit length of the first and the second electrodes 3, 4 in each of the first and the second acoustic wave devices can be different, because of different thicknesses and/or densities, from each other (m1≠m2, where m1 is the mass or mass per unit length of the first and the second electrodes 3, 4 in the first acoustic wave device and m2 is the mass or mass per unit length of the first and the second electrodes 3, 4 in the second acoustic wave device).

If the electronic device further includes a third acoustic wave device, then the mass or mass per unit length of the first and the second electrodes 3, 4 of the third acoustic wave device can be either (a) the same as the mass or mass per unit length of the first and the second electrodes 3, 4 of either the first acoustic wave device or the second acoustic wave device (m3=m1 or m3=m2, where m3 is the mass or mass per unit length of the first and the second electrodes 3, 4 in the third acoustic wave device) or (b) different, because of different thicknesses and/or densities, from the mass or mass per unit length of the first and the second electrodes 3, 4 of both the first and the second acoustic wave devices (m1≠m2≠m3).

FIGS. 19-22 shows electronic devices according to a fifth exemplary embodiment. As shown, both the film thickness of the piezoelectric layer 2 and the mass of each of the first and the second electrodes 3, 4 can be different between the series arm resonators S1, S2, S3 and the parallel arm resonators P1, P2, P3. Only series arm resonator S1 and parallel arm resonators P1, P2 are shown in FIGS. 19-22, but the ladder filter can also use series arm resonators S2, S3 and parallel arm resonator P3.

For example, in FIG. 19, the film thicknesses of the piezoelectric layer 2 of the series arm resonator S1, S2, S3 can be thinner than the film thicknesses of the piezoelectric layer 2 of the parallel arm resonators P1, P2, P3, and the film thicknesses of the first and the second electrodes 3, 4 of the series arm resonator S1, S2, S3 can be thinner than the film thicknesses of the first and the second electrodes 3, 4 of the parallel arm resonators P1, P2, P3. Although shown on the upper surface of the piezoelectric plate 2, it is noted that the first electrode 3 and/or the second electrode 4 can be disposed on the lower surface of the piezoelectric plate 2 in an alternative aspect to face the cavity portion 9.

The relationship between the film thicknesses of the piezoelectric layer 2 and the mass of each of the first and the second electrodes 3, 4 between the series arm resonator S1, S2, S3 and the parallel arm resonators P1, P2, P3 is not limited to relationship shown in FIG. 19.

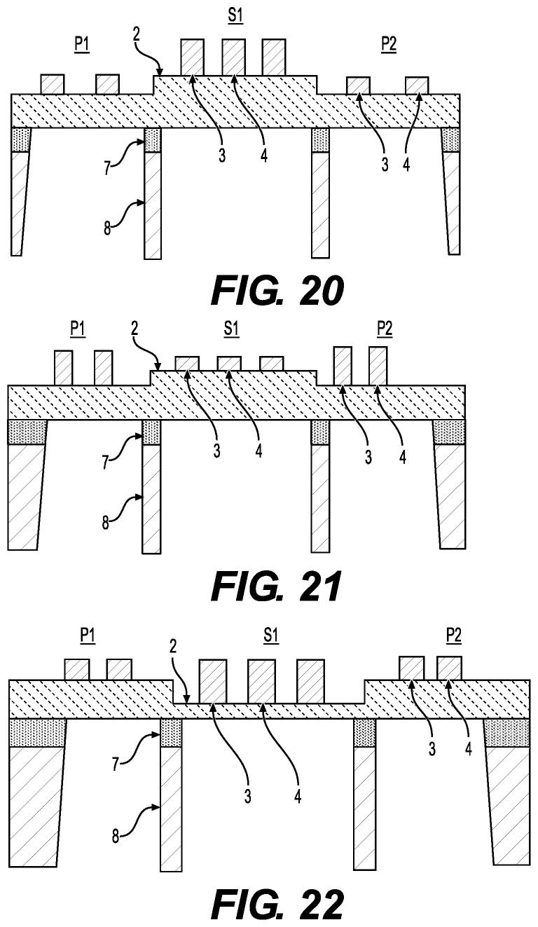

For example, as shown in FIG. 20, the film thicknesses of the piezoelectric layer 2 of the series arm resonators S1, S2, S3 can be thicker than the film thicknesses of the piezoelectric layer 2 of the parallel arm resonators P1, P2, P3, and the film thicknesses of the first and the second electrodes 3, 4 of the series arm resonators S1, S2, S3 can be thicker than the film thicknesses of the first and the second electrodes 3, 4 of the parallel arm resonators P1, P2, P3.

As shown in FIG. 21, the film thicknesses of the piezoelectric layer 2 of the series arm resonators S1, S2, S3 can be thicker than the film thicknesses of the piezoelectric layer 2 of the parallel arm resonators P1, P2, P3, and the film thicknesses of the first electrode 3 and the second electrodes 4 of the series arm resonator S1, S2, S3 can be thinner than the film thicknesses of the first and the second electrodes 3, 4 of the parallel arm resonators P1, P2, P3.

As shown in FIG. 22, the film thicknesses of the piezoelectric layer 2 of the series arm resonators S1, S2, S3 can be thinner than the film thicknesses of the piezoelectric layer 2 of the parallel arm resonators S1, S2, S3, and the film thicknesses of the first and the second electrodes 3, 4 of the series arm resonators S1, S2, S3 can be thicker than the film thicknesses of the first and the second electrodes 3, 4 of the parallel arm resonators P1, P2, P3.

It should be appreciated that other arrangements are also possible. As described above, each of the series arm resonators S1, S2, S3 can include different thicknesses in the piezoelectric layer 2 from each other and/or can include first electrodes 3 and second electrodes 4 with different masses, because of different thicknesses and/or densities, from each other. Also, each of the parallel arm resonators P1, P2, P3 can include different thicknesses in the piezoelectric layer 2 from each other and/or can include first electrodes 3 and second electrodes 4 with different masses, because of different thicknesses and/or densities, from each other.

If the electronic device includes first and second acoustic wave devices, then the film thicknesses of the piezoelectric layer 2 in each of the first and the second acoustic wave devices can be different from each other (t1≠t2) and the masses or mass per unit length of the first and the second electrodes 3, 4 in each of the first and the second acoustic wave devices can be different, because of different thicknesses and/or densities, from each other (m1≠m2).

If the electronic device includes a third acoustic wave device, then either:
(a) the film thickness of the piezoelectric layer 2 of the third acoustic wave device can be the same as the film thickness of the piezoelectric layer 2 of either the first acoustic wave device or the second resonant (t3=t1 or t3=t2) and the mass or mass per unit length of the first and the second electrodes 3, 4 of the third acoustic wave device can be the same as the mass or mass per unit length of the first and the second electrodes 3, 4 of either the first acoustic wave device or the second resonant (m3=m1 or m3=m2); or
(b) the film thickness of the piezoelectric layer 2 of the third acoustic wave device can be different from the film thicknesses of the piezoelectric layer of both the first and the second acoustic wave devices (t1≠t2≠t3) and the mass or mass per unit length of the first and the second electrodes 3, 4 of the third acoustic wave device can be different, because of different thicknesses and/or densities, from the mass or mass per unit length of the first and the second electrodes 3, 4 of both the first and the second acoustic wave devices (m1≠m2≠m3).

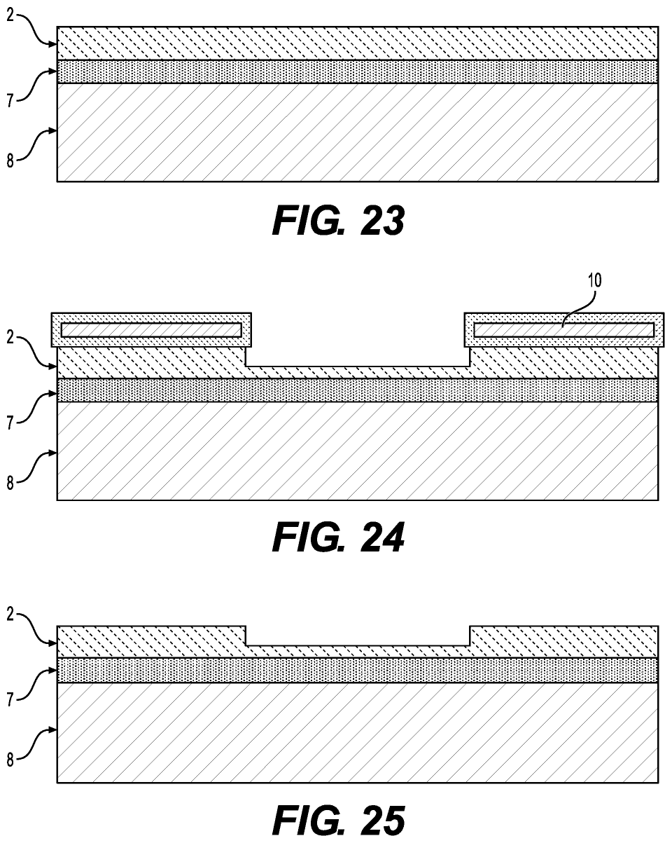

FIGS. 23-29 show a method of manufacturing an electronic device according to a sixth exemplary embodiment. FIG. 23 shows laminating a piezoelectric layer 2 on the support substrate 8 to form the support member. Optionally, as shown in FIG. 23, a dielectric insulating layer 7 can be laminated on the support substrate 8 before the piezoelectric layer 2 is laminated. The support substrate 8 can include silicon or any other suitable material, and the optional dielectric insulating layer 7 can include SiO₂ or any other suitable material.

FIG. 24 shows using a mask 10 to remove a portion of the piezoelectric layer 2, and FIG. 25 shows the removal of the mask 10. Although FIG. 24 shows the removal of only one portion of the piezoelectric layer 2, any number of portions where the thickness of the piezoelectric layer 2 is reduced can be used. The removal of the portion of the piezoelectric layer 2 creates different thicknesses in the piezoelectric layer 2. The portions of the piezoelectric layer 2 that are removed can have any suitable thickness so that any number of different thicknesses can be created in the piezoelectric layer 2. Instead of removing a portion of the piezoelectric layer 2, it is also possible to add portion(s) to create different thicknesses in the piezoelectric layer 2. As described below, different acoustic wave devices can be manufactured on the portions of the piezoelectric layer 2 with different thicknesses.

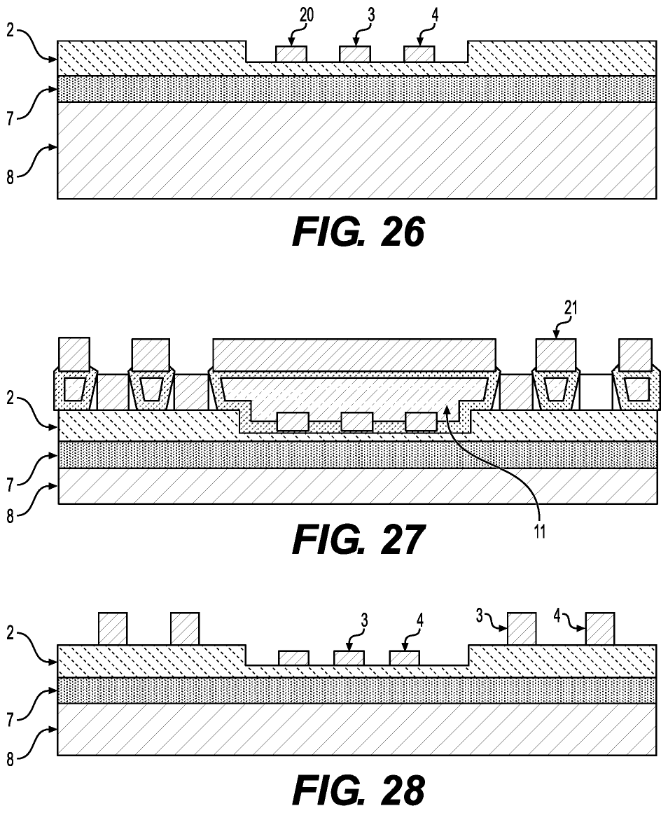

As explained above, the first and the second electrodes 3, 4 of different acoustic wave devices can be formed with different thicknesses. Any number of first and second electrodes 3, 4 can be formed, and the acoustic wave devices can have the same number or a different number of first and second electrodes 3, 4. FIG. 26 shows forming the first and the second electrodes 3, 4 by applying a thin film 20 in a thinner portion of the piezoelectric layer 2. FIG. 27 shows using a resist 11 to form first and second electrodes 3, 4 by applying a thick film 21 on the thicker portions of the piezoelectric layer 2, and FIG. 28 shows removing the resist 11. The thin film 20 and thick film 21 can be applied to the different thicknesses of the piezoelectric layer so that the ratio d/p satisfies d/p<0.5 or d/p<0.24, as discussed above. Alternatively, the thin film 20 can be formed on the thicker portions of the piezoelectric layer 2, and the thick film 20 can be formed on the thinner portion of the piezoelectric layer 2. In addition, instead of applying the thin film 20 before the thick film 21, the thick film 21 can be applied before the thin film 20. Both the thin film 20 and the thick film 21 can be used to form first and second electrodes 3, 4 that can be included in an interdigital transducer electrode such that the first and the second electrodes 3, 4 are interdigitated as described above. The thin film 20 and thick film 21 can be any suitable conductive material and can be the same material or different materials. If different materials are used, then the thin film 20 and thick film 21 can have the same thickness, which could result in the masses or mass per unit length of the first and the second electrodes 3, 4 being different for different acoustic wave devices.

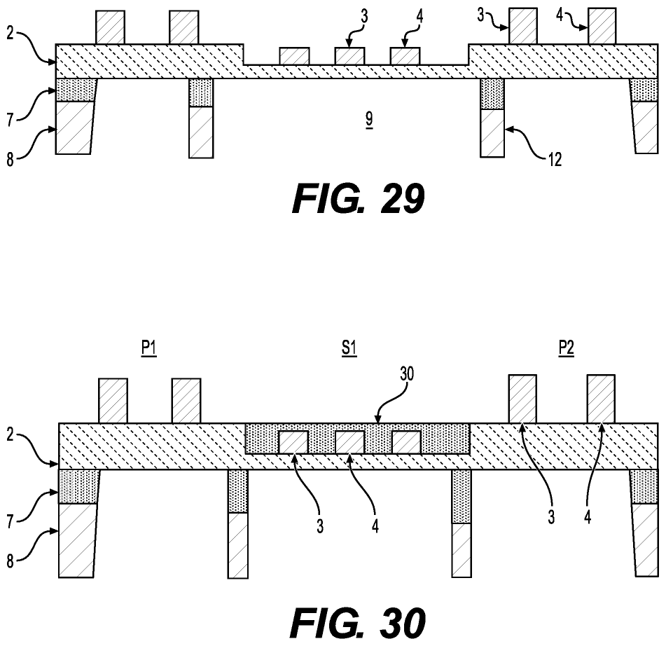

FIG. 29 shows forming cavity portion(s) 9. As shown in FIG. 29, a cavity portion 9 can be formed underneath the first and the second electrodes 3, 4 of each acoustic wave device. Any number of cavity portions 9 can be formed. The cavity portions 9 can be separated by a support portion 12 that extends around the perimeter of each acoustic wave device. The support portion 12 can include the remaining portion of the support substrate 8 and optionally the remaining portion of the dielectrically insulating layer 7.

FIG. 30 shows a seventh exemplary embodiment in which the electronic device includes a protective film 30. The protective film 30 can cover the first and the second electrodes 3, 4 of one or more acoustic wave device. As shown in FIG. 30, the protective film 30 can cover the series arm resonator S1. For example, silicon oxide, nitrogen oxide, or the like can be used as the material of the protective film 30.

As shown in FIG. 30, when the protective film 30 is provided only in a thinner portion of the piezoelectric layer 2, the surface of the protective film 30 can be made flat with respect to the surface of the thicker portion of the piezoelectric layer 2, so adjustment of the frequency can be further performed.

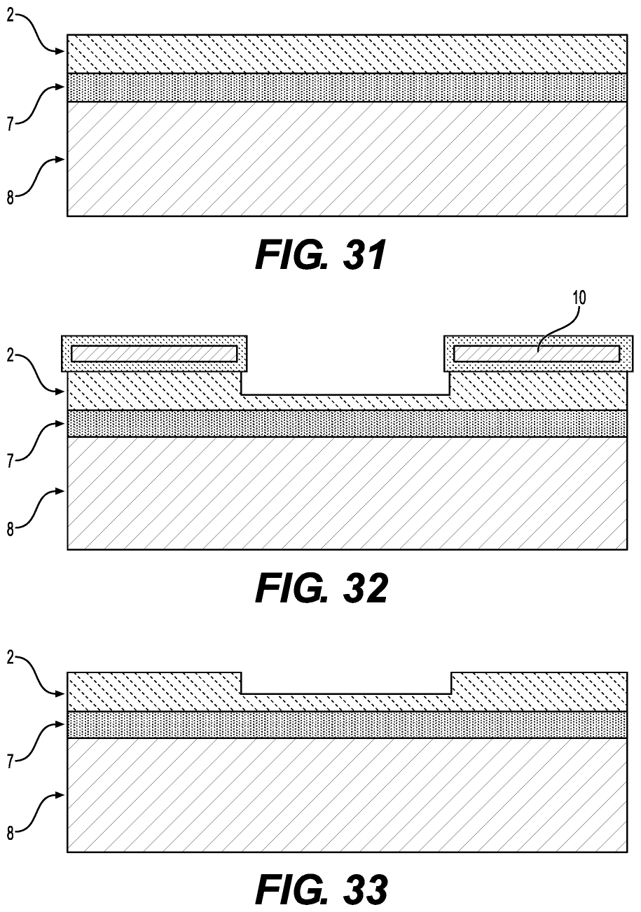

FIGS. 31-39 show a method of manufacturing an electronic device according to an eighth exemplary embodiment in which a protective film 30 is formed. The method according to the eighth embodiment is similar to the method according to the sixth embodiment except that a protective film 30 is formed in the method according to the eighth embodiment. FIG. 31 shows laminating a piezoelectric layer 2 on the support substrate 8. Optionally, as shown in FIG. 31, a dielectric insulating layer 7 can be laminated on the support substrate 8 before the piezoelectric layer 2 is laminated.

FIG. 32 shows using a mask 10 to remove a portion of the piezoelectric layer 2, and FIG. 33 shows the removal of the mask 10.

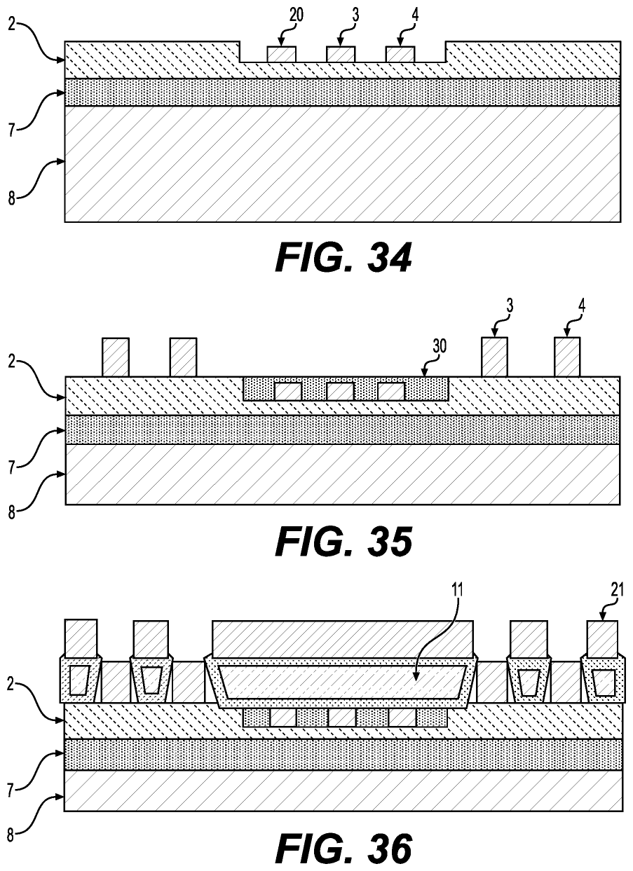

FIG. 34 shows forming the first and the second electrodes 3, 4 by applying a thin film 20 in a thinner portion of the piezoelectric layer 2.

FIG. 35 shows forming a protective film 30 over the first and the second electrodes 3, 4 in the thinner portion of the piezoelectric layer 2. The protective film 30 can include any suitable material, including, for example, silicon oxide and nitrogen oxide. As shown in FIG. 35, the top surface of the protective film 30 can be coextensive or flat with the top surface of the thicker portion of the piezoelectric layer 2.

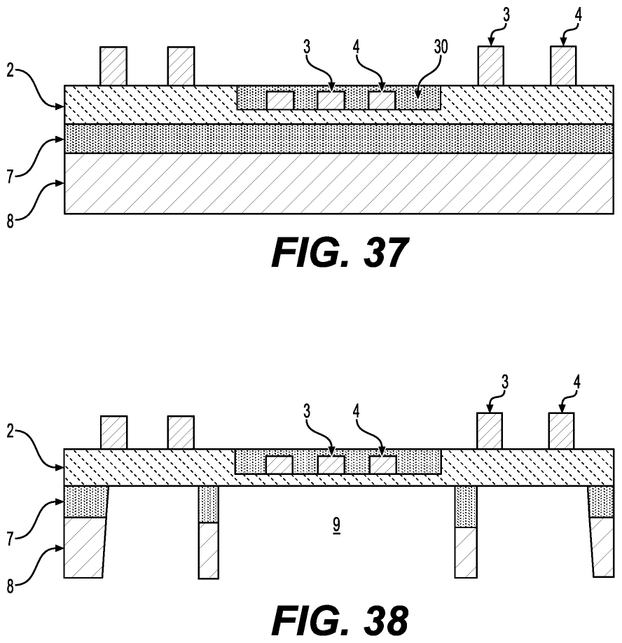

FIG. 36 shows using a resist 11 to form first and second electrodes 3, 4 by applying a thick film 21 on the thicker portions of the piezoelectric layer 2, and FIG. 37 shows removing the resist 11. Alternatively, the thin film 20 can also be formed on the thicker portions of the piezoelectric layer 2, and the thick film 20 can also be formed on the thinner portion of the piezoelectric layer 2. A protective film 30 can be applied to the thick film 20 on the thinner portion of the piezoelectric layer 2.

FIG. 38 shows forming cavity portion(s) 9. As shown in FIG. 38, a cavity portion 9 can be formed underneath the first and the second electrodes 3, 4 of each acoustic wave device.

It should be noted that each of the embodiments described herein is illustrative and that partial substitutions or combinations of configurations are possible among different exemplary embodiments. While exemplary embodiments of the present invention have been described above, it is to be understood that variations and modifications will be apparent to those skilled in the art without departing from the scope and spirit of the present invention.

What is claimed:

1. An acoustic wave device comprising:
a piezoelectric layer comprising at least one of lithium niobate and lithium tantalate;
a series arm resonator including at least a pair of a first electrode and a second electrode on a first portion of the piezoelectric layer; and
a parallel arm resonator including at least a pair of a first electrode and a second electrode on a second portion of the piezoelectric layer,
wherein a film thickness of the first portion of the piezoelectric layer is different than a film thickness of the second portion of the piezoelectric layer.

2. The acoustic wave device according to claim 1, wherein the piezoelectric layer has a film thickness d and a distance between centers of the first electrode and the second electrode adjacent to each other of at least one of the series arm resonator and the parallel arm resonator is p and a ratio d/p is less than or equal to about 0.5.

3. The acoustic wave device according to claim 1, wherein:
a mass of the first electrode in the series arm resonator is different from a mass of the first electrode in the parallel arm resonator, and
a mass of the second electrode in the series arm resonator is different from a mass of the second electrode in the parallel arm resonator.

4. The acoustic wave device according to claim 1, further comprising a protective film over a thinner of the first portion and the second portion of the piezoelectric layer to cover the first electrode and the second electrode of either the series arm resonator or the parallel arm resonator, respectively.

5. The acoustic wave device according to claim 1, wherein the piezoelectric layer includes:
a step portion,
a first connection portion connecting the step portion to a thicker of the first portion and the second portion of the piezoelectric layer, and
a second connection portion connecting the step portion to a thinner of the first portion and the second portion of the piezoelectric layer,
wherein at least one of the first connection portion and the second connection portion includes a curved surface.

6. The acoustic wave device according to claim 1, wherein the piezoelectric layer includes:
a step portion,
a first connection portion connecting the step portion to a thicker of the first portion and the second portion of the piezoelectric layer, and
a second connection portion connecting the step portion to a thinner of the first portion and the second portion of the piezoelectric layer,
wherein the step portion is inclined with respect to a thickness direction of the piezoelectric layer.

7. An acoustic wave device comprising:
a piezoelectric layer comprising at least one of lithium niobate and lithium tantalate; and
a series arm resonator including at least a pair of a first electrode and a second electrode on the piezoelectric layer,
a parallel arm resonator including at least a pair of a first electrode and a second electrode on the piezoelectric layer,
wherein a film thickness of the piezoelectric layer is d and a distance between centers of the first electrode and the second electrode that are adjacent to each other of at least one of the series arm resonator and the parallel arm resonator is p and a ratio d/p is less than or equal to about 0.5, and
wherein a mass per unit length of an electrode finger of the first electrode in the series arm resonator is different from a mass per unit length of an electrode finger of the first electrode in the parallel arm resonator.

8. The acoustic wave device according to claim 2, wherein the ratio d/p is less than or equal to about 0.24 in each of the series arm resonator and the parallel arm resonator.

9. The acoustic wave device according to claim 1, wherein:
a film thickness of the first electrode in the series arm resonator is different from a film thickness of the first electrode in the parallel arm resonator, and
a film thickness of the second electrode in the series arm resonator is different from a film thickness of the second electrode in the parallel arm resonator.

10. The acoustic wave device according to claim 9, wherein:
a film thickness of the first electrode in the series arm resonator is thinner than a film thickness of the first electrode in the parallel arm resonator; and
a film thickness of the second electrode in the series arm resonator is thinner than a film thickness of the second electrode in the parallel arm resonator.

11. The acoustic wave device according to claim 1, wherein a first material of the first electrode and the second electrode in the series arm resonator is different from a second material of the first electrode and the second electrode in the parallel arm resonator.

12. The acoustic wave device according to claim 9, wherein:
a mass of the first electrode in the series arm resonator is less than a mass of the first electrode in the parallel arm resonator, and
a mass of the second electrode in the series arm resonator is less than a mass of the second electrode in the parallel arm resonator.

13. The acoustic wave device according to claim 1, further comprising:
a plurality of the series arm resonators and a plurality of the parallel arm resonators,
wherein at least one of the plurality of series arm resonators and the plurality of parallel arm resonators includes both a resonator that provides a pass band of a ladder filter and a resonator that does not provide the pass band of the ladder filter.

14. The acoustic wave device according to claim 1, further comprising:
a support member including a support substrate that supports the piezoelectric layer; and
a cavity in the support member that overlaps in a plan view with at least a portion of the first electrode or the second electrode of at least one of the series arm resonator and the parallel arm resonator.

15. The acoustic wave device according to claim 1,
wherein an excitation region is a region in which the first electrode and the second electrode that are adjacent and that overlap when viewed in a direction in which the first electrode and the second electrode are opposed, and
wherein a metallization ratio of electrodes to the excitation region is MR and MR≤1.75 (d/p)+0.075 in each of the series arm resonator and parallel arm resonator.

16. The acoustic wave device according to claim 1, wherein:
each of the series arm resonator and the parallel arm resonator includes an interdigital transducer electrode, and
the first electrode and the second electrode comprise electrode fingers of the interdigital transducer electrode.

17. An electronic device comprising:
a support member including a first cavity and a second cavity;
a piezoelectric layer comprising at least one of lithium niobate and lithium tantalate and that is on the support member;
a first acoustic wave device disposed within a first region of the piezoelectric layer over the first cavity; and
a second acoustic wave device disposed within a second region of the piezoelectric layer over the second cavity,
wherein a first thickness of the piezoelectric layer in the first region is different than a second thickness of the piezoelectric layer in the second region.

18. The electronic device of claim 17, wherein the first acoustic wave device is a series arm resonator and the second acoustic wave device is a parallel arm resonator of a ladder filter.

19. The electronic device of claim 17, wherein the piezoelectric layer has a film thickness d and a distance between centers of adjacent electrodes in the first and the second acoustic wave devices is p and a ratio d/p is less than or equal to about 0.5 in each of the first and the second acoustic wave devices.

20. The electronic device of claim 17, wherein, when a metallization ratio of electrodes to the excitation region is MR, MR≤1.75 (d/p)+0.075 in each of the first and the second acoustic wave devices.
